(19) United States
(12) Patent Application Publication
(10) Pub. No.: US 2023/0108080 A1
(43) Pub. Date: Apr. 6, 2023

(54) SEMICONDUCTOR LASER DEVICE

(71) Applicant: Panasonic Holdings Corporation, Osaka (JP)

(72) Inventor: Masaharu FUKAKUSA, Osaka (JP)

(21) Appl. No.: 17/800,774

(22) PCT Filed: Feb. 12, 2021
(86) PCT No.: PCT/JP2021/005367

§ 371 Date: Aug. 18, 2022

(30) Foreign Application Priority Data
Mar. 5, 2020 (JP) 2020-037680

(51) Int. Cl. H01S 5/02253; H01S 5/14; G02B 27/10

(52) U.S. Cl. CPC H01S 5/02253; G02B 27/1006; H01S 5/141

(57) ABSTRACT

A semiconductor laser device includes: a plurality of semiconductor laser elements which emit laser beams with different wavelengths; a plurality of lens portions which collimate the laser beams; a wavelength dispersion element on which the laser beams are incident at different angles, and which changes the traveling directions of the incident laser beams according to the wavelengths to generate an emitted beam that is a combined beam of the laser beams; a plurality of first reflective surfaces which cause the laser beams to be incident on the wavelength dispersion element at the angles corresponding to the laser beams; and a plurality of second reflective surfaces which guide the laser beams to the plurality of first reflective surfaces.

### CROSS-REFERENCE OF RELATED APPLICATIONS

This application is the U.S. National Phase under 35 U.S.C. § 371 of International Patent Application No. PCT/JP2021/005367, filed on Feb. 12, 2021, which in turn claims the benefit of Japanese Patent Application No. 2020-037680, filed on Mar. 5, 2020, the entire disclosures of which Applications are incorporated by reference herein.

### TECHNICAL FIELD

The present invention relates to a semiconductor laser device, and is suitable for use in, for example, processing a product.

### BACKGROUND ART

In recent years, various products have been processed using laser beams emitted from a semiconductor laser device. In this type of semiconductor laser device, it is preferable to increase the output of emitted beam in order to increase the processing quality.

Patent Literature (PTL) 1 described below discloses a semiconductor laser device which increases the output of the emitted beam by using a diffraction grating to combine the laser beams emitted from a plurality of semiconductor laser elements with different emission wavelengths. Here, the semiconductor laser elements are arranged close to each other along the circumference centered on the diffraction grating.

### CITATION LIST

### Patent Literature

[PTL 1] Japanese Unexamined Patent Application Publication No. 2016-54295

### SUMMARY OF INVENTION

### Technical Problem

As described above, when a plurality of semiconductor laser elements are arranged close to each other, the heat generated by one of the semiconductor laser elements influences the semiconductor laser elements adjacent to the one semiconductor laser element. This results in a problem in which each semiconductor laser element is not capable of providing sufficient light output.

The problem can be solved by increasing the distance between each adjacent semiconductor laser element in the circumferential direction. However, when combining laser beams with different wavelengths by a diffraction grating, it is necessary to arrange a plurality of semiconductor laser elements in a predetermined angle range centered on the diffraction grating. Accordingly, when the distance between each adjacent semiconductor laser element is increased as described above, the number of semiconductor laser elements that can be arranged in the predetermined angle range decreases, which results in a decrease in output of the emitted beam.

In view of such a problem, an object of the present invention is to provide a semiconductor laser device capable of effectively increasing the output of the emitted beam generated by combining the laser beams with different wavelengths.

### Solution to Problem

A main aspect of the present invention relates to a semiconductor laser device. A semiconductor laser device according to the aspect includes: a plurality of semiconductor laser elements which emit laser beams with wavelengths that are different from each other; a plurality of lens portions which collimate the laser beams; a wavelength dispersion element on which the laser beams are incident at angles that are different from each other, the wavelength dispersion element changing traveling directions of the laser beams according to the wavelengths to generate a combined beam of the laser beams; a plurality of first reflective surfaces which cause the laser beams to be incident on the wavelength dispersion element at the angles corresponding to the laser beams; and a plurality of second reflective surfaces which guide the laser beams to the plurality of first reflective surfaces.

With the semiconductor laser device according to the aspect, even when the distance between each adjacent semiconductor laser element is increased, adjustment of the arrangement of the second reflective surfaces allow the laser beams emitted from the semiconductor laser elements to be guided to the first reflective surfaces. In addition, adjustment of the arrangement of the first reflective surfaces allows each laser beam to be incident on the wavelength dispersion element at an appropriate angle. Accordingly, a large number of semiconductor laser elements can be arranged while reducing the influence of heat between the semiconductor laser elements. As a result, the output of the emitted beam generated by combining the laser beams with different wavelengths can be effectively increased.

### Advantageous Effects of Invention

As described above, according to the present invention, it is possible to provide a semiconductor laser device and an external cavity laser device capable of effectively increasing the output of the emitted beam generated by combining laser beams with different wavelengths.

The advantageous effects and significance of the present invention will be further clarified by the description of the embodiments below. However, the embodiments below are merely examples of an implementation of the present invention, and the present invention is not limited to the following embodiments.

### BRIEF DESCRIPTION OF DRAWINGS

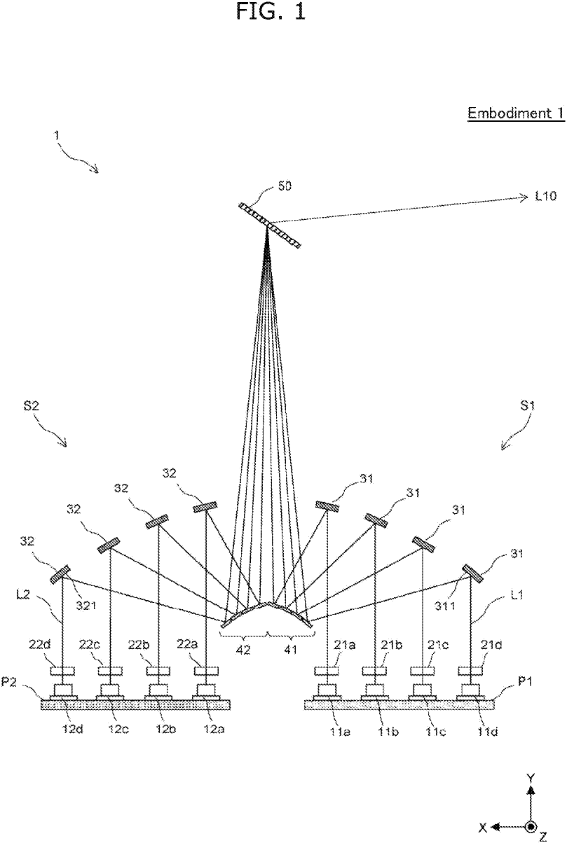

### Fig. 1

FIG. 1 illustrates a configuration of a semiconductor laser device according to Embodiment 1.

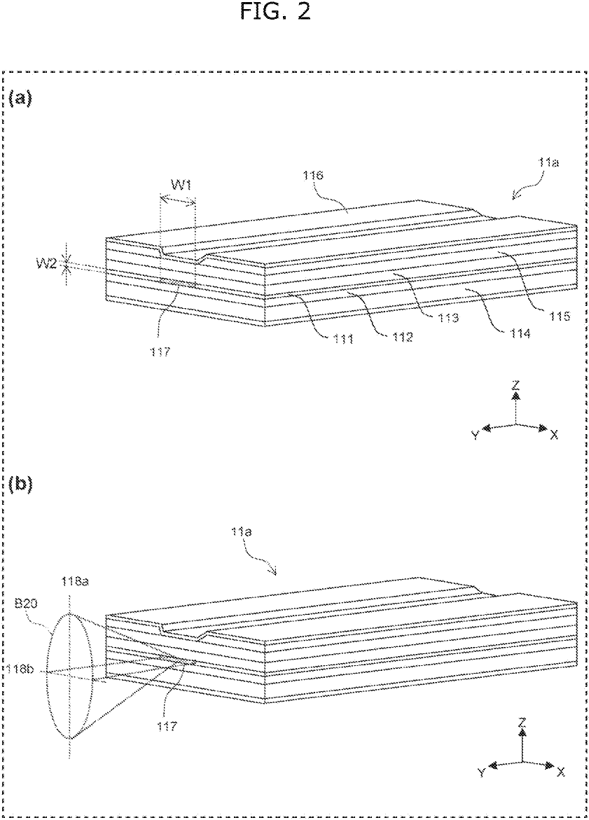

### Fig. 2

FIG. 2 is a perspective view of a configuration of a semiconductor laser element according to Embodiment 1.

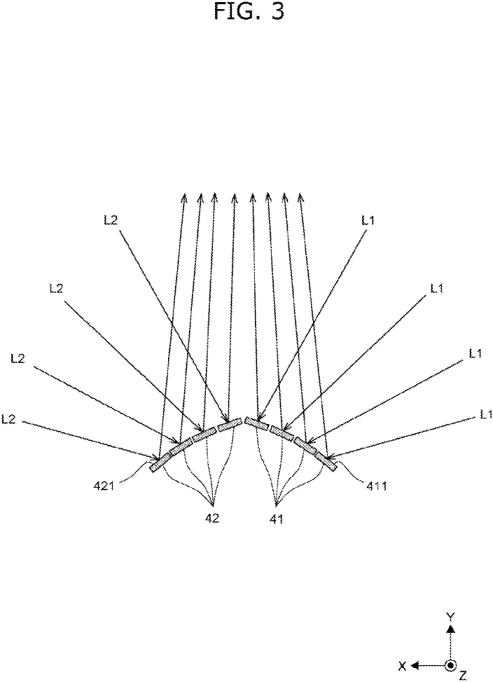

### Fig. 3

FIG. 3 is an enlarged view of a portion of an optical system according to Embodiment 1.

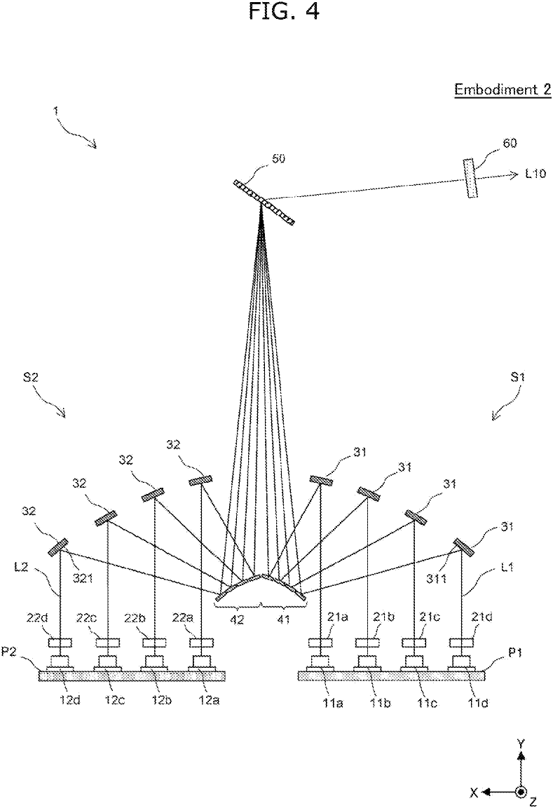

### Fig. 4

FIG. 4 illustrates a configuration of a semiconductor laser device according to Embodiment 2.

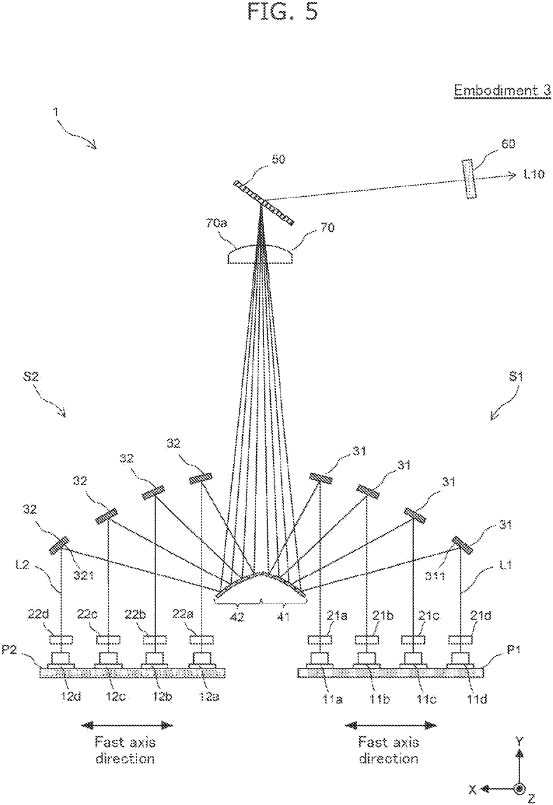

### Fig. 5

FIG. 5 illustrates a configuration of a semiconductor laser device according to Embodiment 3.

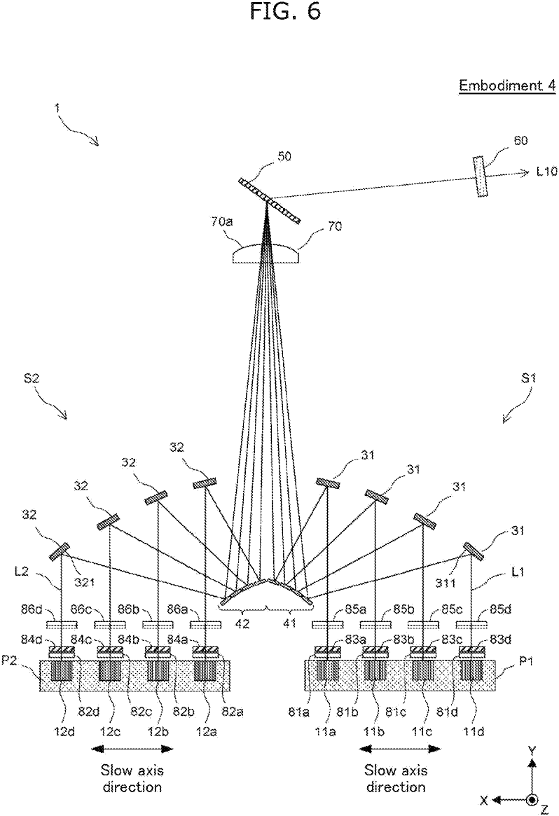

### Fig. 6

FIG. 6 illustrates a configuration of a semiconductor laser device according to Embodiment 4.

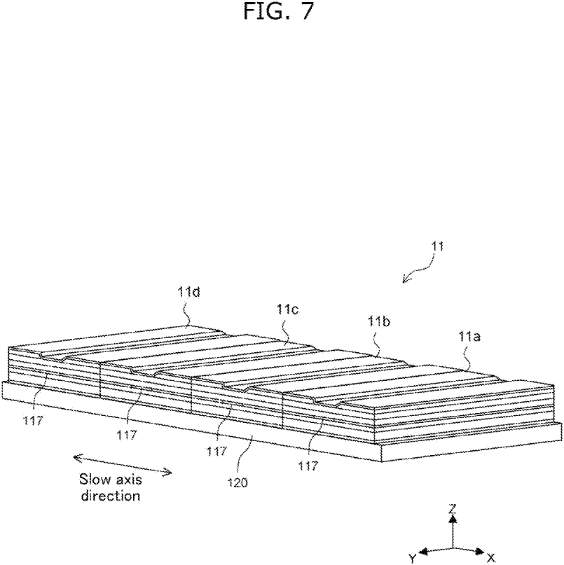

### Fig. 7

FIG. 7 is a perspective view of a configuration of a laser array according to Embodiment 4.

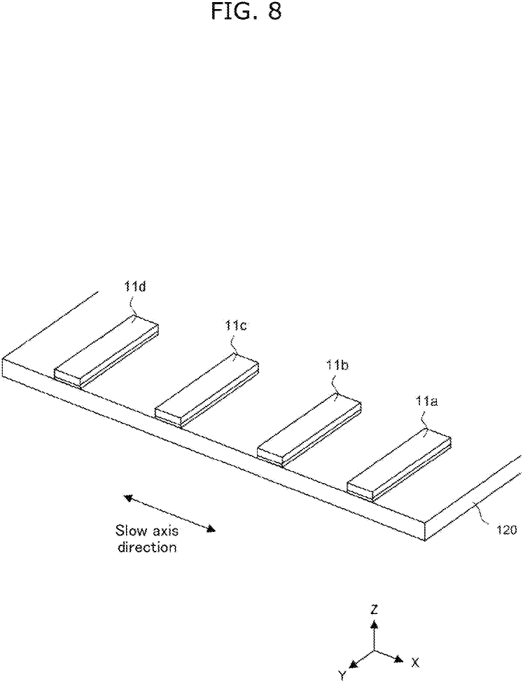

### Fig. 8

FIG. 8 is a perspective view of an arrangement form of semiconductor laser elements according to a variation of Embodiment 4.

### DESCRIPTION OF EMBODIMENTS

Hereinafter, embodiments of the present invention will be described with reference to the drawings. It should be noted that each of the embodiments described below shows a specific example of the present invention. Accordingly, the numerical values, shapes, materials, structural elements, the arrangement positions and connection form of the structural elements, and the like illustrated in the following embodiments are examples, and are not intended to limit the present invention. Therefore, among the structural elements in the following embodiments, the structural elements not described in independent claims are described as arbitrary structural elements.

Note that the drawings are represented schematically and are not necessarily precise illustrations. As such, the scaling, etc., depicted in the drawings is not necessarily accurate. In the drawings, like reference signs indicate like elements, and overlapping descriptions thereof are omitted or simplified. For the purpose of convenience, each drawing includes mutually orthogonal X, Y, and Z axes. The X-axis direction is aligned with the arrangement direction of the semiconductor laser elements, and the Y-axis direction is aligned with the direction in which a laser beam is emitted from a semiconductor laser element.

### Embodiment 1

In Embodiment 1, reflective surfaces 411 and 421 of mirrors 41 and 42 correspond to “first reflective surfaces” in the claims, and reflective surfaces 311, 321 of mirrors 31 and 32 correspond to “second reflective surfaces” in the claims. Moreover, in Embodiment 1, collimator lenses 21a to 21d and collimator lenses 22a to 22d correspond to “lens portions” in the claims.

However, the above description is intended to associate the elements of the claims with the elements of Embodiment 1, and such an association does not limit the invention recited in the claims to the elements of the embodiments.

FIG. 1 illustrates a configuration of semiconductor laser device 1.

Semiconductor laser device 1 includes optical system S1, optical system S2, and diffraction grating 50.

Optical system S1 includes four semiconductor laser elements 11a to 11d, four collimator lenses 21a to 21d, four mirrors 31, and four mirrors 41. Optical system S2 includes four semiconductor laser elements 12a to 12d, four collimator lenses 22a to 22d, four mirrors 32, and four mirrors 42. The number of semiconductor laser elements arranged in each of optical system S1 and optical system S2 is not limited to four, and may be a plurality of semiconductor laser elements other than four.

FIG. 2 is a perspective view of a configuration of semiconductor laser element 11a.

As illustrated in (a) of FIG. 2, semiconductor laser element 11a has a structure in which active layer 111 is sandwiched between N-type clad layer 112 and P-type clad layer 113. N-type clad layer 112 is stacked on N-type substrate 114. Contact layer 115 is stacked on P-type clad layer 113. When a current is applied to electrode 116, a laser beam is emitted from light-emitting region 117 in the positive Z-axis direction. Generally, width W1 of light-emitting region 117 in the direction parallel to active layer 111 is greater than width W2 of light-emitting region 117 in the direction perpendicular to active layer 111.

The axis of light-emitting region 117 in the widthwise direction, that is, the axis in the direction perpendicular to active layer 111 (Z-axis direction) is referred to as a fast axis, and the axis of light-emitting region 117 in the lengthwise direction, that is, the axis in the direction parallel to active layer 111 (X-axis direction) is referred to as a slow axis. In (b) of FIG. 2, 118a indicates the fast axis, and 118b indicates the slow axis. The laser beam emitted from light-emitting region 117 has a larger beam divergence angle along the fast axis than along the slow axis. Hence, as illustrated in (b) of FIG. 2, beam B20 has an elliptical shape that is long along the fast axis.

Each of semiconductor laser elements 11a to 11d and 12a to 12d illustrated in FIG. 1 has the same configuration as those in (a) and (b) of FIG. 2. Semiconductor laser elements 11a to 11d and 12a to 12d emit laser beams with wavelengths that are different from each other. The emission wavelength bands of semiconductor laser elements 11a to 11d and 12a to 12d are different from each other by approximately, for example, a few nanometers (for example, 1 nm) between adjacent semiconductor laser elements. The emission wavelength bands of semiconductor laser elements 11a to 11d and 12a to 12d are set to, for example, around 390 nm to 450 nm. In Embodiment 1, as semiconductor laser elements 11a to 11d and 12a to 12d, for example, distributed feedback (DFB) laser elements or distributed Bragg reflector (DBR) laser elements are used.

Referring back to FIG. 1, semiconductor laser elements 11a to 11d are disposed on heat radiation plate P1 and semiconductor laser elements 12a to 12d are disposed on heat radiation plate P2 while being housed separately in CAN. Semiconductor laser elements 11a to 11d and 12a to 12d are arranged in a line along the X-axis. Four mirrors 41 are spaced apart from four semiconductor laser elements 11a to 11d in the positive X-axis direction. Moreover, four mirrors 42 are spaced apart from four semiconductor laser elements 12a to 12d in the negative X-axis direction.

In the subsequent stage of semiconductor laser elements 11a to 11d, four collimator lenses 21a to 21d which circumferentially collimate laser beams L1 emitted from semiconductor laser elements 11a to 11d are arranged. Similarly, in the subsequent stage of semiconductor laser elements 12a to 12d, four collimator lenses 22a to 22d which circumferentially collimate laser beams L2 emitted from semiconductor laser elements 12a to 12d are arranged.

In the subsequent stage of collimator lenses 21a to 21d, four mirrors 31 which guide laser beams L1, which have passed through collimator lenses 21a to 21d, to four mirrors 41 are arranged. Similarly, in the subsequent stage of collimator lenses 22a to 22d, four mirrors 32 which guide laser beams L2, which have passed through collimator lenses 22a to 22d, to four mirrors 42 are arranged. Mirrors 31 and 32 are plate-shaped mirrors having reflective surfaces 311 and 321 on the negative Y-axis side.

Four mirrors 31 are positioned opposite to semiconductor laser elements 11a to 11d in the Y-axis direction. In a plane view from the positive Y-axis side, four mirrors 31 and corresponding semiconductor laser elements 11a to 11d are arranged along the same lines. Four mirrors 31 are arranged such that as mirrors 31 are positioned further in the positive direction of the X-axis, mirrors 31 shift in the positive direction of the Y-axis, so as not to block laser beam L1 reflected by reflective surface 311 of mirror 31 positioned adjacent in the negative direction of the X-axis.

Four mirrors 32 are positioned opposite to semiconductor laser elements 12a to 12d in the Y-axis direction. In a plane view from the positive Y-axis side, four mirrors 32 and corresponding semiconductor laser elements 12a to 12d are arranged in the same lines. Four mirrors 32 are arranged such that as mirrors 32 are positioned further in the negative direction of the X-axis, mirrors 32 shift in the positive direction of the Y-axis, so as not to block laser beam L2 reflected by reflective surface 321 of mirror 32 positioned adjacent in the positive direction of the X-axis.

Four mirrors 31 are arranged such that reflective surfaces 311 are arranged in a generally parabolic shape on a plane parallel to the X-Y plane. Similarly, four mirrors 32 are arranged such that reflective surfaces 321 are arranged in a generally parabolic shape on a plane parallel to the X-Y plane. The inclination angles of reflective surfaces 311 of four mirrors 31 are different from each other, and the inclination angles of reflective surfaces 321 of four mirrors 32 are different from each other.

Four mirrors 41 reflect laser beams L1 reflected by four mirrors 31, so that laser beams L1 are incident on the incident surface of diffraction grating 50 at approximately the same position. Four mirrors 42 reflect laser beams L2 reflected by four mirrors 32, so that laser beams L2 are incident on the incident surface of diffraction grating 50 at approximately the same position. The positions on the incident surface of diffraction grating 50 where laser beams L1 and L2 are incident are approximately the same.

Mirrors 41 and 42 are plate-shaped mirrors which have reflective surfaces 411 and 421 on the positive Y-axis side. In a plane view from the positive Y-axis side, four mirrors 41 and semiconductor laser elements 11a to 11d are arranged along the same lines. Similarly, in a plane view from the positive Y-axis side, four mirrors 42 and semiconductor laser elements 12a to 12d are arranged along the same lines. Accordingly, four mirrors 41 and four mirrors 42 are arranged in a line in the X-axis direction.

FIG. 3 is an enlarged view of the vicinity of mirrors 41 and 42.

Four mirrors 41 are arranged such that as mirrors 41 are positioned further in the positive direction of the X-axis, mirrors 41 shift in the positive direction of the Y-axis. Four mirrors 42 are arranged such that as mirrors 42 are positioned further in the negative direction of the X-axis, mirrors 42 shift in the positive direction of the Y axis. Four mirrors 41 are positioned such that reflective surfaces 411 are arranged in a generally parabolic shape on a plane parallel to the X-Y plane. Similarly, four mirrors 42 are positioned such that reflective surfaces 421 are arranged in a generally parabolic shape on a plane parallel to the X-Y plane. The inclination angles of reflective surfaces 411 of four mirrors 41 are different from each other, and the inclination angles of reflective surfaces 421 of four mirrors 42 are different from each other.

Referring back to FIG. 1, laser beams L1 reflected by mirrors 41 and laser beams L2 reflected by mirrors 42 are incident on diffraction grating 50 at different angles. Diffraction grating 50 changes the traveling directions of incident laser beams L1 and L2 at diffraction angles that are in accordance with the wavelengths, so that laser beams L1 and L2 are combined. In other words, the optical axes of laser beams L1 and L2, which have passed through diffraction grating 50, are aligned with each other, so that emitted beam L10 is generated. Emitted beam L10 is used, for example, for processing a product.

Diffraction grating 50 is arranged so as to be inclined at a predetermined angle relative to the direction parallel to the X-Y plane. Diffraction grating 50 has a diffraction pattern (pitch and depth of diffraction grooves) set such that laser beams L1 and L2 with respective wavelengths incident at predetermined angles are diffracted in the same traveling direction. Moreover, the arrangement (position in the Y-axis direction and inclination) of mirrors 31 and 32 and mirrors 41 and 42 are arranged such that laser beams L1 and L2 with respective wavelengths are incident on diffraction grating 50 at the corresponding angles.

Similarly, the arrangement (intervals in the X-axis direction) of semiconductor laser elements 11a to 11d and 12a to 12d is adjusted together with the arrangement of mirrors 31, 32 and mirrors 41 and 42 such that laser beam L1 and L2 with respective wavelengths are incident on diffraction grating 50 at the corresponding incident angles. As a result, as described above, the optical axes of laser beams L1 and L2, which have passed through diffraction grating 50, can be aligned, and emitted beam L10 that is a combined beam of laser beams L1 and L2 can be generated.

In the configuration of FIG. 1, the angle of diffraction grating 50 and the incident angle of each laser beam are arranged such that the oscillation wavelengths of semiconductor laser elements 11a to 11d and 12a to 12d satisfy the relation of λ12d < λ12c < λ12b < λ12a < λ11a < λ11b < λ11c < λ11d.

### Advantageous Effects of Embodiment 1

According to Embodiment 1, the following advantageous effects are obtained.

Even when the distance between adjacent ones of semiconductor laser elements 11a to 11d and 12a to 12d is increased, laser beams L1 and L2 emitted from semiconductor laser elements 11a to 11d and 12a to 12d can be guided to reflective surfaces 411 and 421 (first reflective surfaces) of mirrors 41 and 42 by adjusting the arrangement of reflective surfaces 311 and 321 (second reflective surfaces) of mirrors 31 and 32. In addition, adjustment of the arrangement of reflective surfaces 411 and 421 (first reflective surfaces) of mirrors 41 and 42 causes each of laser beams L1 and L2 to be incident on diffraction grating 50 (wavelength dispersion element) at an appropriate angle. Accordingly, a large number of semiconductor laser elements 11a to 11d and 12a to 12d can be arranged while reducing the influence of heat between semiconductor laser elements 11a to 11d and 12a to 12d. As a result, the output of emitted beam L10 generated by combining laser beams L1 and L2 with different wavelengths can be effectively increased.

Moreover, as illustrated in FIG. 1, semiconductor laser elements 11a to 11d and 12a to 12d are arranged in a line in the X-axis direction. Reflective surfaces 411 and 421 (first reflective surfaces) of mirrors 41 and 42 are spaced apart from semiconductor laser elements 11a to 11d and 12a to 12d in the direction in which semiconductor laser elements 11a to 11d and 12a to 12d are arranged. Reflective surfaces 311 and 321 (second reflective surfaces) of mirrors 31 and 32 are arranged such that reflective surfaces 311 and 321 (second reflective surfaces) closer to reflective surfaces 411 and 421 (first reflective surfaces) are positioned farther from semiconductor laser elements 11a to 11d and 12a to 12d. As a result, laser beam L1 reflected by reflective surface 311 of one mirror 31 and laser beam L2 reflected by reflective surface 321 of one mirror 32 can be appropriately made incident on reflective surfaces 411 and 421 of corresponding mirrors 41 and 42 without being blocked by the other mirrors 31 and 32. Accordingly, the output of emitted beam L10 can be smoothly increased.

Moreover, as illustrated in FIG. 1, optical system S1 (set) including semiconductor laser elements 11a to 11d, collimator lenses 21a to 21d (lens portions), four reflective surfaces 411 (first reflective surfaces), and four reflective surfaces 311 (second reflective surfaces), and optical system S2 (set) including semiconductor laser elements 12a to 12d, collimator lenses 22a to 22d (lens portions), four reflective surfaces 421 (first reflective surfaces), and four reflective surfaces 321 (second reflective surfaces) are arranged in the direction in which semiconductor laser elements 11a to 11d and 12a to 12d are arranged (X-axis direction) such that reflective surfaces 411 of optical system S1 are adjacent to reflective surfaces 421 (first reflective surfaces) of optical system S2. By arranging two optical systems S1 and S2 symmetrically in one direction in such a manner, the number of semiconductor laser elements 11a to 11d and 12a to 12d that can be arranged can be significantly increased. Accordingly, the output of emitted beam L10 can be increased more effectively.

Moreover, in Embodiment 1, diffraction grating 50 is used as a wavelength dispersion element. With this, adjustment of the diffraction pattern (pitch and depth of the diffraction grooves) allows laser beams L1 and L2 of respective wavelengths to be smoothly combined.

### Embodiment 2

FIG. 4 illustrates a configuration of semiconductor laser device 1 according to Embodiment 2.

As compared with Embodiment 1, Embodiment 2 additionally includes partial reflective mirror 60 which reflects, toward diffraction grating 50, part of emitted beam L10 from diffraction grating 50 to cause the part of emitted beam L10 to travel back to semiconductor laser elements 11a to 11d and 12a to 12d. Moreover, semiconductor laser elements 11a to 11d and 12a to 12d are changed to external cavity semiconductor laser elements. In other words, in Embodiment 2, partial reflective mirror 60 and semiconductor laser elements 11a to 11d and 12a to 12d define an external resonator. Traveling back of the reflected beams from partial reflective mirror 60 to semiconductor laser elements 11a to 11d and 12a a to 12d causes external resonances of semiconductor laser elements 11a to 11d and 12a to 12d at different wavelengths. The other configurations are the same as those in Embodiment 1.

Since the angular arrangement of diffraction grating 50 and the incident angle of each laser beam are the same as those in Embodiment 1, external resonant wavelengths λ11a to λ11d and λ12a to λ12d of semiconductor laser elements 11a to 11d and 12a to 12d satisfy the relation of λ12d < λ12c < λ12b < λ12a< λ11a < λ11b < λ11c < λ11d.

The wavelength band which allows the external resonance of semiconductor laser elements 11a to 11d and 12a to 12d is approximately 30 nm to 40 nm. Semiconductor laser elements 11a to 11d and 12a to 12d oscillate due to the external resonance within this wavelength band. It is preferable that the compositions of semiconductor laser elements 11a to 11d and 12a to 12d are adjusted so as to have a gain peak near the wavelength at which oscillation due to external resonance occurs. With this, semiconductor laser elements 11a to 11d and 12a to 12d can be efficiently oscillated at the time of external resonance, and the outputs of semiconductor laser elements 11a to 11d and 12a to 12d can be increased.

Also in Embodiment 2, the emission wavelength band of semiconductor laser elements 11a to 11d and 12a to 12d may be set to, for example, approximately 390 nm to 450 nm in a similar manner to Embodiment 1.

### Advantageous Effects of Embodiment 2

In Embodiment 2, the same advantageous effects as those of Embodiment 1 can be obtained.

Moreover, according to Embodiment 2, partial reflective mirror 60 and semiconductor laser elements 11a to 11d and 12a to 12d define an external resonator. Hence, even without precise adjustment of the incident angles of laser beams L1 and L2 emitted from semiconductor laser elements 11a to 11d and 12a to 12d on diffraction grating 50, semiconductor laser elements 11a to 11d and 12a to 12d oscillate at wavelengths at which laser beams L1 and L2 are properly combined to emitted beam L10. Accordingly, with simple adjustment, the output of emitted beam L10 can be increased effectively.

### Embodiment 3

FIG. 5 illustrates a configuration of semiconductor laser device 1 according to Embodiment 3.

As compared with Embodiment 2, Embodiment 3 additionally includes fast axis collimator lens 70 which collimate laser beams L1 and L2 to be incident on diffraction grating 50 in the fast axis direction. Semiconductor laser elements 11a to 11d and 12a to 12d are arranged in the fast axis direction. In other words, semiconductor laser elements 11a to 11d and 12a to 12d are arranged such that the fast axis is parallel to the X-axis. The other configurations in Embodiment 3 are the same as those in Embodiment 2.

In Embodiment 3, fast axis collimator lens 70 corresponds to the “an other lens portion” in claim 5.

Fast axis collimator lens 70 includes lens surface 70a that curves only in the direction parallel to the X-Y plane. The generatrix of lens surface 70a is parallel to the Z axis.

### Advantageous Effects of Embodiment 3

In the configuration of Embodiment 2, laser beams L1 and L2 emitted from semiconductor laser elements 11a to 11d and 12a to 12d are collimated by collimator lenses 21a to 21d and 22a to 22d, respectively. However, collimated laser beams L1 and L2 do not become perfect parallel beams, and are incident on diffraction grating 50 while being slightly diverged relative to the parallel beams. Accordingly, laser beams L1 and L2 include a beam that is not incident on diffraction grating 50 at an appropriate angle, and such a beam deviates from emitted beam L10.

On the other hand, in Embodiment 3, fast axis collimator lens 70 further makes laser beams L1 and L2 incident on diffraction grating 50 closer to the parallel beams in the fast axis direction. Accordingly, as compared with Embodiment 2, the amount of beams that are not incident on diffraction grating 50 at an appropriate angle can be reduced, so that more beams can be combined into emitted beam L10. This increases the output of emitted beam L10 more effectively. In addition, since the amount of beams traveling back from partial reflective mirror 60 can be secured, laser beams L1 and L2 can be efficiently emitted from semiconductor laser elements 11a to 11d and 12a to 12d.

In Embodiment 3, semiconductor laser elements 11a to 11d and 12a to 12d are arranged in the fast axis direction. Hence, laser beams L1 and L2 emitted from semiconductor laser elements 11a to 11d and 12a to 12d approach each other in the fast axis direction as the distance to diffraction grating 50 decreases, and overlap on the light receiving surface of diffraction grating 50. Accordingly, when an error occurs in the arrangement of the optical components, laser beams L1 and L2 are misaligned in the fast axis direction on the light receiving surface of diffraction grating 50. However, due to the high beam quality in the fast axis direction, it is possible to increase the allowable misalignment range which allows the entire beam quality of emitted beam L10 to be maintained. Accordingly, by arranging semiconductor laser elements 11a to 11d and 12a to 12d in the fast axis direction in such a manner, the beam quality of emitted beam L10 can be increased, and the arrangement of the optical components can be easily adjusted.

The configuration illustrated in Embodiment 3, that is, the configuration in which semiconductor laser elements 11a to 11d and 12a to 12d are arranged in the fast axis direction and fast axis collimator lens 70 is disposed may be applied to the configuration of Embodiment 1. With this, the same advantageous effects as described above can be obtained.

### Variations

In the configuration of FIG. 5, similarly to the configuration of FIG. 1 in Embodiment 1, reflective surfaces 311 of four mirrors 31 are arranged in a generally parabolic shape on a plane parallel to the X-Y plane, and reflective surfaces 411 of four mirrors 41 are arranged in a generally parabolic shape on a plane parallel to the X-Y plane. Such a feature also applies to reflective surfaces 321 of four mirrors 32 and reflective surfaces 421 of four mirrors 42.

In addition, since the angular arrangement of diffraction grating 50 and the incident angle of each laser beam are also the same as those in Embodiment 1, an external resonator is defined such that wavelengths λ11a to λ11d and λ12ato λ12d of semiconductor laser elements 11a to 11d and 12a to 12d satisfy the relation of λ12d < λ12c < λ12b < λ12a< λ11a < λ11b < λ11c < λ11d.As described above, with respect to semiconductor laser elements 11a to 11d and 12a to 12d, the external resonant wavelengths are shorter as semiconductor laser elements 11a to 11d and 12a to 12d are positioned further in the positive direction of the X axis.

On the other hand, since laser beams L1 and L2 of all wavelengths are incident on fast-axis collimator lens 70, chromatic aberration occurs for each laser beam (for each wavelength). In addition, as described above, since the wavelengths of semiconductor laser elements 11a to 11d and 12a to 12d are different from each other, the convergence effect is different between respective laser beams (respective wavelengths). Hence, it is preferable that the configuration of FIG. 5 further includes a configuration for appropriately collimating the laser beams with respective wavelengths.

In view of this point, in the present variation, optical systems S1 and S2 are configured such that, among semiconductor laser elements 11a to 11d and 12a to 12d, semiconductor laser elements with shorter emission wavelengths have shorter optical path lengths to fast-axis collimator lens 70. Specifically, the optical path length between each of semiconductor laser elements 11a to 11d and 12a to 12d and fast axis collimator lens 70 is adjusted as described above by the arrangement of reflective surfaces 311 of four mirrors 31 and reflective surfaces 321 of four mirrors 32.

The shorter the wavelength is, the shorter the focal length of fast axis collimator lens 70 is. Accordingly, by configuring optical systems S1 and S2 such that the shorter the emission wavelength of the semiconductor laser element is, the shorter the optical path length to fast-axis collimator lens 70 is, laser beams L1 and L2 with respective wavelengths can be appropriately collimated by fast axis collimator lens 70. Accordingly, the output of emitted beam L10 can be increased more effectively.

It is preferable that the optical path length between each of semiconductor laser elements 11a to 11d and 12a to 12d and fast-axis collimator lens 70 is adjusted such that laser beams L1 and L2 with respective wavelengths are appropriately collimated by fast-axis collimator lens 70. In this case, too, for example, the optical path length between each of semiconductor laser elements 11a to 11d and 12a to 12d and fast-axis collimator lens 70 may be adjusted by the arrangement of reflective surfaces 311 of four mirrors 31 and reflective surfaces 321 of four mirrors 32.

In the configuration of FIG. 5, among semiconductor laser elements 11a to 11d and 12a to 12d, semiconductor laser elements positioned further in the positive direction of the X axis have shorter wavelengths. Accordingly, the adjustment may be made such that optical path lengths L1a to L1d and L2a to L2d between semiconductor laser elements 11a to 11d and 12a to 12d to fast axis collimator lens 70 satisfy the relation of L2d < L2c < L2b < L2a < L1a < L1b < L1c < L1d. With this, it can be realized that the shorter the emission wavelength of the semiconductor laser device is, the shorter the optical path length to fast-axis collimator lens 70 is.

### Embodiment 4

FIG. 6 illustrates a configuration of semiconductor laser device 1 according to Embodiment 4.

In Embodiment 4, the configurations of the stages prior to mirrors 31 and 32 are different from those in Embodiment 3. In other words, in Embodiment 4, semiconductor laser elements 11a to 11d are disposed on heat radiation plate P1, and semiconductor laser elements 12a to 12d are disposed on heat radiation plate P2 so as to be arranged in the slow axis direction. Moreover, in the stages subsequent to semiconductor laser elements 11a to 11d and 12a to 12d, fast axis collimator lenses 81a to 81d and 82a to 82d, beam rotation elements 83a to 83d and 84a to 84d, and slow axis collimator lenses 85a to 85d and 86a to 86d are arranged. The other configurations in Embodiment 4 are the same as those in Embodiment 3.

In Embodiment 4, four semiconductor laser elements 11a to 11d are arrayed. Similarly, four semiconductor laser elements 12a to 12d are also arrayed.

FIG. 7 is a perspective view of a configuration of laser array 11.

As illustrated in FIG. 7, four semiconductor laser elements 11a to 11d are arranged on base 120 along the slow axis to form laser array 11. Accordingly, light-emitting regions 117 of semiconductor laser elements 11a to 11d are aligned in the slow axis direction. A laser array including four semiconductor laser elements 12a to 12d also has the same configuration.

In FIG. 7, laser array 11 is configured such that four semiconductor laser elements 11a to 11d are disposed adjacent to each other on base 120. However, one semiconductor light-emitting element including four light-emitting regions 117 arranged in the slow axis direction may be disposed on base 120. In this case, among the semiconductor light-emitting elements, the structural portions that emit the laser beams from respective light-emitting regions 117 correspond to semiconductor laser elements 11a to 11d. Four semiconductor laser elements 12a to 12d may also be arrayed by one semiconductor light-emitting element including four light-emitting regions 117 arranged in the slow axis direction.

Referring back to FIG. 6, the laser arrays thus configured are disposed on heat dissipation plates P1 and P2. With this, semiconductor laser elements 11a to 11d and 12a to 12d are aligned in the slow axis direction.

Fast axis collimator lenses 81a to 81d and 82a to 82d collimate laser beams L1 and L2 emitted from semiconductor laser elements 11a to 11d and 12a to 12d in the fast axis direction. Fast axis collimator lenses 81a to 81d and 82a to 82d are made of, for example, cylindrical lenses. In this case, fast axis collimator lenses 81a to 81d and 82a to 82d are arranged such that the generatrix of each lens surface is parallel to the X axis.

Beam rotation elements 83a to 83d and 84a to 84d rotate the fast axes and the slow axes of laser beams L1 and L2. Each of beam rotation elements 83a to 83d and 84a to 84d is, for example, an optical element which has incident and exit surfaces that are outwardly convexed cylindrical surfaces. The generatrixes of the cylindrical surfaces are parallel to each other. The cylindrical surfaces of each of beam rotation element 83a to 83d and 84a to 84d have a same shape, and share a focal point inside beam rotation elements 83a to 83d and 84a to 84d.

In this case, beam rotation elements 83a to 83d and 84a to 84d are arranged such that the generatrix of each cylindrical surface is 45 degrees with respect to the fast axes and the slow axes of incident laser beams L1 and L2. As a result, laser beams L1 and L2, which have passed through beam rotation elements 83a to 83d and 84a to 84d, rotate in one direction about the optical axis as the distances from laser beams L1 and L2 to slow axis collimator lenses 85a to 85d and 86a to 86d decrease.

Slow axis collimator lenses 85a to 85d and 86a to 86d are arranged at positions where the slow axes of incident laser beams L1 and L2 are parallel to the Z axis. As a result, laser beams L1 and L2 are incident on corresponding slow axis collimator lenses 85a to 85d and 86a to 86d in a state where the slow axis is parallel to the Z axis and the fast axis is parallel to the X axis.

Slow axis collimator lenses 85a to 85d and 86a to 86d collimate incident laser beams L1 and L2 in the slow axis direction. Slow axis collimator lenses 85a to 85d and 86a to 86d are made of, for example, cylindrical lenses. In this case, slow axis collimator lenses 85a to 85d and 86a to 86d are arranged such that the generatrix of each of the lens surfaces is parallel to the X axis. Slow axis collimator lenses 85a to 85d and 86a to 86d have lens surfaces (cylindrical surfaces) on the sides where laser beams L1 and L2 exit.

When laser beams L1 and L2 are incident on the lens surfaces (incident surfaces) of slow axis collimator lenses 85a to 85d and 86a to 86d, the rotation of beams caused by beam rotation elements 83a to 83d and 84a to 84d is stopped due to the optical effects of the lens surfaces. Accordingly, laser beams L1 and L2, which have passed through slow axis collimator lenses 85a to 85d and 86a to 86d travel to fast axis collimator lens 70 with the fast axes parallel to the X axis, in a similar manner to Embodiment 3.

### Advantageous Effects of Embodiment 4

Embodiment 4 also provides the same advantageous effects as those of Embodiment 3.

In Embodiment 4, since semiconductor laser elements 11a to 11d and semiconductor laser elements 12a to 12d are arrayed, arrangement and position adjustment of semiconductor laser elements 11a to 11d and 12a to 12d can be easily performed.

Note that the configuration illustrated in the variation of Embodiment 3 may be similarly applied to Embodiment 4.

In addition, in the configuration of FIG. 6, semiconductor laser elements 11a to 11d and 12a to 12d and partial reflective mirror 60 define an external resonator. However, it may be that semiconductor laser elements 11a to 11d and 12a to 12d oscillate due to internal resonance. In this case, partial reflective mirror 60 is eliminated from the configuration of FIG. 6, and semiconductor laser elements 11a to 11d and 12a to 12d are changed to internal cavity semiconductor laser elements as in Embodiment 1.

Moreover, it may be that each of semiconductor laser elements 11a to 11d and 12a to 12d is formed of a laser array element including a plurality of emitters, and that each of beam rotation elements 83a to 83d and 84a to 84d includes a lens array including a plurality of cylindrical lens surfaces so as to correspond to the plurality of emitters.

Note that semiconductor laser elements 11a to 11d do not always have to be integrally formed, and may be separated from each other, for example, as illustrated in FIG. 8.

### Other Variations

Although the embodiments of the present invention have been described above, the present invention is not limited to the above embodiments, and various changes can be made to the embodiments.

For example, in each of Embodiments 1 to 4, a total of eight semiconductor laser elements 11a to 11d and 12a to 12d are arranged, but the number of semiconductor laser elements is not limited to eight. For example, more semiconductor laser elements may be arranged in optical systems S1 and S2. Moreover, the number of semiconductor laser elements arranged in optical system S1 may be different from the number of semiconductor laser elements arranged in optical system S2.

In each of Embodiments 1 to 4, a total of eight reflective surfaces 311 and 321 are spaced apart from each other, but reflective surfaces 311 and 321 do not always have to be spaced apart from each other. For example, one mirror may include four reflective surfaces 311 with different inclination angles while sharing boundaries without being separated from each other. Reflective surfaces 321 may be configured in the same manner. The same also applies to reflective surfaces 411 and 421.

In Embodiments 1 to 4, the distance between adjacent ones of semiconductor laser elements 11a to 11d is constant, but the distance between adjacent ones of semiconductor laser elements 11a to 11d does not always have to be constant. The same also applies to semiconductor laser elements 12a to 12d.

In the above embodiments, semiconductor laser elements 11a to 11d and 12a to 12d are arranged in a straight line, but semiconductor laser elements 11a to 11d and 12a to 12d do not always have to be arranged in a straight line. For example, in the configuration of FIG. 1, semiconductor laser elements 11b and 11d may be arranged at positions shifted in the Z-axis direction with respect to semiconductor laser elements 11a and 11c. In this case, mirrors 31 opposite to semiconductor laser elements 11b and 11d are inclined in the direction parallel to the Y-Z plane in accordance with the shift of semiconductor laser elements 11b and 11d, so that laser beams L1 emitted from semiconductor laser elements 11b and 11d are guided to corresponding mirrors 41. Moreover, these two mirrors 41 are inclined in the direction parallel to the Y-Z plane such that laser beams L1 reflected by two mirrors 41 are incident on a common incident position on diffraction grating 50.

Moreover, mirrors 41 and 42 may be shifted in the Z-axis direction with respect to mirrors 31 and 32. With this configuration, the inclinations of mirrors 41 and 42 may be adjusted such that diffraction grating 50 is shifted in the Z-axis direction in accordance with the shift of mirrors 41 and 42, and laser beams L1 and L2 reflected by mirrors 41 and 42 are incident on the common incident position on diffraction grating 50. In this case, laser beams L1 and L2 reflected by mirrors 41 and 42 do not pass through the gap between mirror 31 positioned at the end in the positive X-axis direction and mirror 32 positioned at the end in the negative X-axis direction. Hence, the optical systems in the stages prior to mirrors 31 and 32 may be arranged close to each other so as to eliminate this gap.

In Embodiments 1 to 4 described above, two optical systems S1 and S2 are arranged in semiconductor laser device 1, but only one of the optical systems may be arranged in semiconductor laser device 1.

In Embodiments 1 to 4, transmissive diffraction grating 50 is used as the wavelength dispersion element, but a reflective diffraction grating may be used as the wavelength dispersion element. Instead of diffraction grating 50, another wavelength dispersion element, such as a prism, may be used.

In Embodiments 1 to 3, one type of collimator lenses 21a to 21d and 22a to 22d are used as the “lens portion” described in the claims. However, the “lens portion” may include a combination of cylindrical lenses which collimate laser beams L1 and L2 in the fast axis direction and cylindrical lenses which collimate laser beams L1 and L2 in the slow axis direction. Moreover, “an other lens portion” in the claims does not always have to include one type of fast-axis collimator lens 70, but may include a combination of a plurality of lenses.

The configuration of semiconductor laser device 1 is not limited to the configurations illustrated in Embodiments 1 to 4, and can be modified in various manners. For example, a mirror that bends the optical paths of laser beams L1 and L2 may be disposed between mirrors 41 and 42 and diffraction grating 50. An optical element, such as a lens, may be appropriately arranged in the subsequent stage of diffraction grating 50.

Semiconductor laser device 1 may be used not only in the processing of products, and may be used for other purposes.

In addition, various modifications may be made to the embodiments of the present invention as appropriate within the scope of the technical idea indicated in the claims. For example, other forms in which various modifications apparent to those skilled in the art are applied to the embodiments, or forms structured by combining structural elements and functions of different embodiments may be included within the present invention unless such changes and modifications depart from the scope of the present invention.

1. A semiconductor laser device comprising:
a plurality of semiconductor laser elements which emit laser beams with wavelengths that are different from each other;
a plurality of lens portions which collimate the laser beams;
a wavelength dispersion element on which the laser beams are incident at angles that are different from each other, the wavelength dispersion element changing traveling directions of the laser beams according to the wavelengths to generate a combined beam of the laser beams;
a plurality of first reflective surfaces which cause the laser beams to be incident on the wavelength dispersion element at the angles corresponding to the laser beams; and
a plurality of second reflective surfaces which guide the laser beams to the plurality of first reflective surfaces.

2. The semiconductor laser device according to claim 1,
wherein the plurality of semiconductor laser elements are arranged in a line,
the plurality of first reflective surfaces are spaced apart from the plurality of semiconductor laser elements in a direction in which the plurality of semiconductor laser elements are arranged; and
among the plurality of second reflective surfaces, a second reflective surface positioned closer to the plurality of first reflective surfaces is positioned farther from the plurality of semiconductor laser elements.

3. The semiconductor laser device according to claim 2,
wherein two sets each including at least one of the plurality of semiconductor laser elements, at least one of the plurality of lens portions, at least one of the plurality of first reflective surfaces, and at least one of the plurality of second reflective surfaces are arranged in the direction in which the plurality of semiconductor laser elements are arranged, the at least one of the plurality of first reflective surfaces in a first one of the two sets being adjacent to the at least one of the plurality of first reflective surfaces in a second one of the two sets.

4. The semiconductor laser device according to claim 1 , comprising
a partial reflective mirror which reflects part of an emitted beam from the wavelength dispersion element toward the wavelength dispersion element to cause the part of the emitted beam to travel back to the plurality of semiconductor laser elements,
the partial reflective mirror and the plurality of semiconductor laser elements define an external resonator, and
external resonances of the plurality of semiconductor laser elements occur at wavelengths that are different from each other.

5. The semiconductor laser device according to claim 1 ,
wherein the plurality of semiconductor laser elements are aligned in a fast axis direction, and
the semiconductor laser device further comprises
an other lens portion which collimates the laser beams to be incident on the wavelength dispersion element in the fast axis direction.

6. The semiconductor laser device according to claim 1 ,
wherein the plurality of semiconductor laser elements are aligned in a slow axis direction,
the semiconductor laser device further comprises:
a plurality of beam rotation elements which rotate fast axes of the laser beams by approximately 90 degrees; and
an other lens portion which collimates the laser beams to be incident on the wavelength dispersion element in a fast axis direction.

7. The semiconductor laser device according to claim 6,
wherein each of the plurality of lens portions includes:
a fast axis collimator lens which is disposed in a stage prior to the plurality of beam rotation elements, the fast axis collimator lens collimating a laser beam emitted from a corresponding one of the plurality of semiconductor laser elements in the fast axis direction; and
a slow axis collimator lens which is disposed in a stage subsequent to the plurality of beam rotation elements, the slow axis collimator lens collimating the laser beam in the slow axis direction.

8. The semiconductor laser device according to claim 6,
wherein the plurality of semiconductor laser elements are arrayed.

9. The semiconductor laser device according to claim 5 ,
wherein, among the plurality of semiconductor laser elements, a semiconductor laser element with a shorter emission wavelength has a shorter optical path length to the other lens portion.

10. The semiconductor laser device according to claim 9,
wherein an optical path length between each of the plurality of semiconductor laser elements and the other lens portion is adjusted by an arrangement of the plurality of second reflective surfaces.

11. The semiconductor laser device according to claim 1,
wherein the wavelength dispersion element is a diffraction grating.
